(19) United States
(12) Patent Application Publication
(10) Pub. No.: US 2025/0336653 A1
(43) Pub. Date: Oct. 30, 2025

(54) SUBSTRATE PROCESSING APPARATUS AND ELECTROSTATIC CHUCK

(71) Applicant: Tokyo Electron Limited, Tokyo (JP)

(72) Inventor: Shinsuke OKA, Miyagi (JP)

(73) Assignee: Tokyo Electron Limited, Tokyo (JP)

(21) Appl. No.: 19/262,292

(22) Filed: Jul. 8, 2025

Related U.S. Application Data
(63) Continuation of application No. PCT/JP2024/001071, filed on Jan. 17, 2024.
(60) Provisional application No. 63/480,701, filed on Jan. 20, 2023.

(51) Int. Cl. H01J 37/32

(52) U.S. Cl. CPC H01J 37/32715; H01J 37/32642; H01J 2237/002; H01J 2237/2007

(57) ABSTRACT

A substrate processing apparatus and an electrostatic chuck for preventing or inhibiting occurrence of abnormal discharge at a lower part of edge ring are provided. Substrate processing apparatus includes: plasma processing chamber; base table situated in plasma processing chamber; electrostatic chuck situated on base table and having substrate support surface and ring support surface; and edge ring situated on ring support surface. Groove in which heat transfer gas is diffused is formed in at least one of ring support surface or lower surface of edge ring. Heat transfer gas supply hole configured to supply heat transfer gas into groove is formed in ring support surface. In annular region including position at which heat transfer gas supply hole is formed, depth of groove in surrounding region around heat transfer gas supply hole is less than depth of groove in region other than surrounding region.

### CROSS-REFERENCE TO RELATED APPLICATIONS

This application is a continuation application of International Application No. PCT/JP2024/001071, filed on Jan. 17, 2024, and designating the U.S., which is based upon and claims priority to U.S. Patent Application No. 63/480,701, filed on Jan. 20, 2023, the entire contents of each are incorporated herein by reference.

### BACKGROUND

### Technical Field

This disclosure relates to a substrate processing apparatus and an electrostatic chuck.

### Background Art

A plasma processing apparatus for performing plasma processing on a substrate includes a chamber and a substrate support provided in the chamber. The substrate support has an electrostatic chuck for holding the substrate. The electrostatic chuck is provided with a through-hole for supplying a heat transfer gas, such as helium gas and the like, to between the substrate and the surface of the electrostatic chuck. An example of such a plasma processing apparatus is described in Japanese Patent Application Laid-Open Publication No. 2018-93173.

Japanese Patent Application Laid-Open Publication No. 2019-216176 specifies that an annular groove is provided on the circumference of the back surface of an edge ring.

### SUMMARY

In order to solve the above problem, according to one embodiment, there is provided a substrate processing apparatus, including: a plasma processing chamber; a base table situated in the plasma processing chamber; an electrostatic chuck situated on the base table and having a substrate support surface and a ring support surface; and an edge ring situated on the ring support surface, wherein a groove in which a heat transfer gas is diffused is formed in at least one of the ring support surface or a lower surface of the edge ring; and a heat transfer gas supply hole configured to supply the heat transfer gas into the groove is formed in the ring support surface; and in an annular region including a position at which the heat transfer gas supply hole is formed, a depth of the groove in a surrounding region around the heat transfer gas supply hole is less than a depth of the groove in a region other than the surrounding region.

### BRIEF DESCRIPTION OF THE DRAWINGS

FIG. 1 is a diagram showing an example of the configuration of a plasma processing system;

FIG. 2 is a diagram showing an example of the configuration of a capacitively coupled plasma processing apparatus;

FIG. 3 is an example of a top view of an electrostatic chuck 1111;

FIG. 4 is an example of a diagram schematically showing a cross-section around an edge ring situated on an annular region of a ceramic member according to a first embodiment, cut at a position near a heat transfer gas supply hole;

FIG. 5 is an example of a diagram schematically showing a cross-section around an edge ring situated on an annular region of a ceramic member according to the first embodiment, cut at a position apart from a heat transfer gas supply hole;

FIG. 6 is an example of a diagram schematically showing a cross-section around an edge ring situated on an annular region of a ceramic member according to a second embodiment, cut at a position near a heat transfer gas supply hole;

FIG. 7 is an example of a diagram schematically showing a cross-section around an edge ring situated on an annular region of a ceramic member according to the second embodiment, cut at a position apart from a heat transfer gas supply hole;

FIG. 8 is an example of a diagram schematically showing a cross-section around an edge ring situated on an annular region of a ceramic member according to a third embodiment, cut at a position near a heat transfer gas supply hole;

FIG. 9 is an example of a diagram schematically showing a cross-section around an edge ring situated on an annular region of a ceramic member according to the third embodiment, cut at a position apart from a heat transfer gas supply hole;

FIG. 10 is an example of a diagram schematically showing a cross-section around an edge ring situated on an annular region of a ceramic member according to a fourth embodiment, cut at a position near a heat transfer gas supply hole;

FIG. 11 is an example of a diagram schematically showing a cross-section around an edge ring situated on an annular region of a ceramic member according to the fourth embodiment, cut at a position apart from a heat transfer gas supply hole;

FIG. 12 is an example of a diagram schematically showing a cross-section around an edge ring situated on an annular region of a ceramic member according to a fifth embodiment, cut at a position near a heat transfer gas supply hole;

FIG. 13 is an example of a diagram schematically showing a cross-section around an edge ring situated on an annular region of a ceramic member according to the fifth embodiment, cut at a position apart from a heat transfer gas supply hole;

FIG. 14 is an example of a diagram schematically showing a cross-section of a ceramic member in which a groove is formed; and

FIG. 15 is an example of a diagram schematically showing a cross-section of a ceramic member in which a groove is formed.

### DETAILED DESCRIPTION OF THE DISCLOSURE

Various exemplary embodiments will be described in detail below with reference to the drawings. In the drawings, the same reference numerals are assigned to the same or corresponding parts.

### [Plasma Processing System]

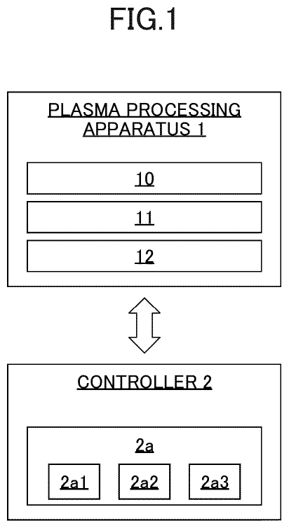

A plasma processing system according to the present disclosure will be described with reference to FIG. 1. FIG. 1 is an example of a diagram for explaining an example of the configuration of a plasma processing system. In one embodiment, the plasma processing system includes a plasma processing apparatus (substrate processing apparatus) 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma forming part 12. The plasma processing chamber 10 includes a plasma processing space. The plasma processing chamber 10 includes at least one gas supply port for supplying at least one processing gas to the plasma processing space, and at least one gas exhaust port for exhausting a gas from the plasma processing space. The gas supply port is connected to a gas supply 20 described later, and the gas exhaust port is connected to a gas exhaust system 40 described later. The substrate support 11 is situated in the plasma processing space and has a substrate support surface for supporting a substrate.

The plasma forming part 12 is configured to form a plasma from at least one processing gas supplied into the plasma processing space. The plasma formed in the plasma processing space may be a Capacitively Coupled Plasma (CCP), an Inductively Coupled Plasma (ICP), an Electron-Cyclotron-Resonance (ECR) plasma, a Helicon Wave Plasma (HWP), a Surface Wave Plasma (SWP), and the like. Various types of plasma forming parts may be used, including an Alternating Current (AC) plasma forming part and a Direct Current (DC) plasma forming part. In one embodiment, an AC signal (AC power) used in the AC plasma forming part has a frequency in the range of 100 kHz to 10 GHz. Thus, the AC signal includes a Radio Frequency (RF) signal and a microwave signal. In one embodiment, an RF signal has a frequency in the range of 100 kHz to 150 MHz.

The controller 2 processes computer-executable instructions that cause the plasma processing apparatus 1 to perform various steps described herein. The controller 2 may be configured to control each component of the plasma processing apparatus 1 to perform the various steps described herein. In one embodiment, part or all of the controller 2 may be included in the plasma processing apparatus 1. The controller 2 may include a processor 2al, a memory 2a2, and a communication interface 2a3. The controller 2 may be implemented by, for example, a computer 2a. The processor 2al may be configured to read out a program from the memory 2a2 and execute the read-out program to perform various control operations. The program may be previously stored in the memory 2a2, or may be acquired via a medium when necessary. The acquired program is stored in the memory 2a2, and is read out from the memory 2a2 and executed by the processor 2al. The medium may be any of various types of memory media readable by the computer 2a, or may be a communication line connected to the communication interface 2a3. The processor 2al may be a Central Processing Unit (CPU). The memory 2a2 may include a Random Access Memory (RAM), a Read Only Memory (ROM), a Hard Disk Drive (HDD), and a Solid State Drive (SSD), or a combination thereof. The communication interface 2a3 may communicate with the plasma processing apparatus 1 via a communication line, such as a Local Area Network (LAN) and the like. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

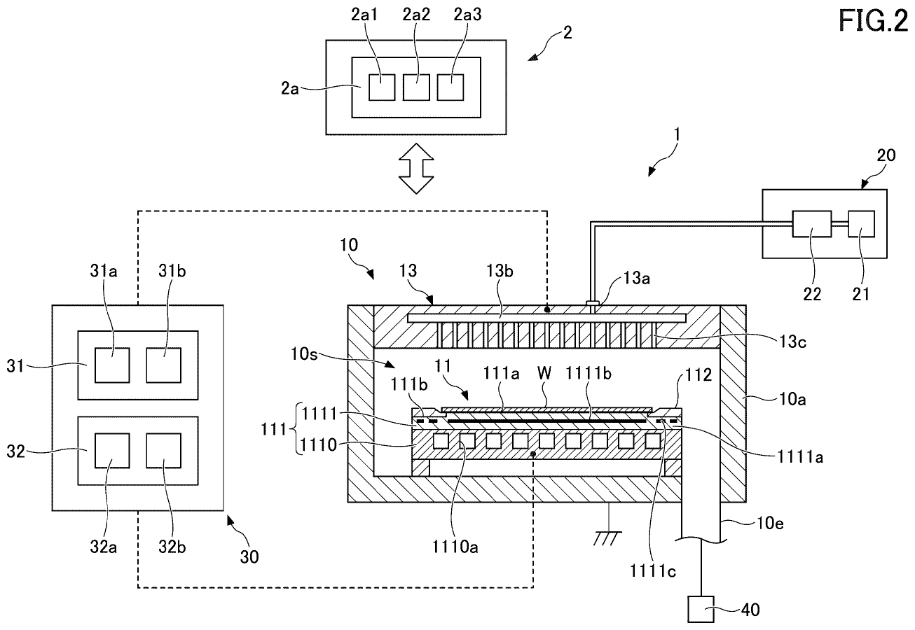

An example of the configuration of a capacitively coupled plasma processing apparatus as an example of the plasma processing apparatus 1 will be described below. FIG. 2 is an example of a diagram for explaining an example of the configuration of the capacitively coupled plasma processing apparatus.

The capacitively coupled plasma processing apparatus 1 includes a plasma processing chamber 10, a gas supply 20, a power source 30, and a gas exhaust system 40. The plasma processing apparatus 1 includes a substrate support 11 and a gas introduction part. The gas introduction part is configured to introduce at least one processing gas into the plasma processing chamber 10. The gas introduction part includes a shower head 13. The substrate support 11 is situated in the plasma processing chamber 10. The shower head 13 is situated above the substrate support 11. In one embodiment, the shower head 13 constitutes at least a part of the ceiling of the plasma processing chamber 10. The plasma processing chamber 10 includes a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central region 111a for supporting a substrate W and an annular region 1l1b for supporting the ring assembly 112. A wafer is an example of the substrate W. The annular region 111b of the body 111 surrounds the central region 111a of the body 111 in a plan view. The substrate W is placed on the central region 111a of the body 111, and the ring assembly 112 is situated on the annular region 111b of the body 111 so as to surround the substrate W on the central region 111a of the body 111. Thus, the central region 111a is also referred to as a substrate support surface for supporting the substrate W, and the annular region 111b is also referred to as a ring support surface for supporting the ring assembly 112.

In one embodiment, the body 111 includes a base table 1110 and an electrostatic chuck 1111. The base table 1110 includes a conductive member. The conductive member of the base table 1110 may function as a lower electrode. The electrostatic chuck 1111 is situated on the base table 1110. The electrostatic chuck 1111 includes a ceramic member 1111a, an electrostatic electrode 1111b situated inside the ceramic member 1111a, and electrostatic electrodes 111c situated inside the ceramic member 1111a. The ceramic member 1111a includes the central region 111a. In one embodiment, the ceramic member 1111a also includes annular region 111b. The electrostatic electrode 1111b is provided in the central region 111a for supporting the substrate W. The electrostatic electrodes 111c are provided in the annular region 111b for supporting the ring assembly 112. Other members surrounding the electrostatic chuck 1111, such as an annular electrostatic chuck, an annular insulating member, and the like, may include the annular region 111b. In this case, the ring assembly 112 may be situated on the annular electrostatic chuck or the annular insulating member, and may be situated on both the electrostatic chuck 1111 and the annular insulating member. Also, at least one RF/DC electrode coupled to either or both of an RF power source 31 and a DC power source 32, which will be described later, may be situated in the ceramic member 1111a. In this case, at least one RF/DC electrode functions as a lower electrode. When either or both of a bias RF signal and a DC signal, which will be described later, is supplied to the at least one RF/DC electrode, the RF/DC electrode is also referred to as a bias electrode. The conductive member of the base table 1110 and at least one RF/DC electrode may function as a plurality of lower electrodes. The electrostatic electrode 1111b may function as a lower electrode. Therefore, the substrate support 11 includes at least one lower electrode.

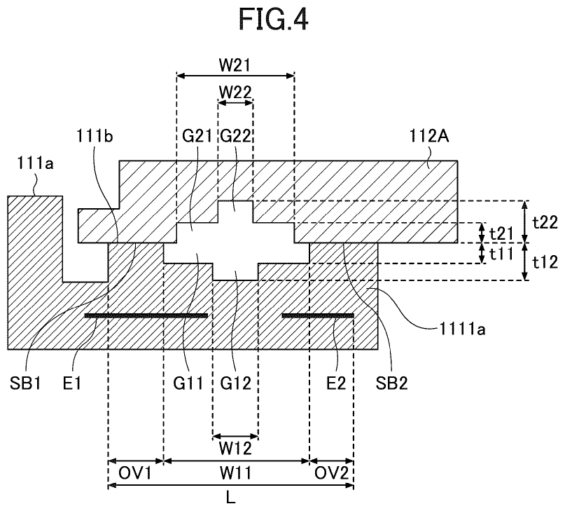

The ring assembly 112 includes one or a plurality of annular members. In one embodiment, the one or the plurality of annular members include one or a plurality of edge rings 112A (see FIG. 4 and the like described below) and at least one cover ring. The edge rings 112A are formed of a conductive material or an insulating material, and the cover ring is formed of an insulating material.

The substrate support 11 may also include a temperature regulating module configured to regulate at least one of the electrostatic chuck 1111, the ring assembly 112, or a substrate to a target temperature. The temperature regulating module may include a heater, a heat transfer medium, a flow path 1110a, or a combination thereof. A heat transfer fluid, such as brine or gas, flows through the flow path 1110a. In one embodiment, the flow path 1110a is formed in the base table 1110, and one or a plurality of heaters are situated in the ceramic member 1111a of the electrostatic chuck 1111. The substrate support 11 may also include a first heat transfer gas supply configured to supply a heat transfer gas to the gap between the back surface of the substrate W and the central region 111a. The substrate support 11 may also include a second heat transfer gas supply configured to supply a heat transfer gas to the gap between the bottom surface of the edge ring 112A and the annular region 1l1b.

The shower head 13 is configured to introduce at least one processing gas from the gas supply 20 into the plasma processing space 10s. The shower head 13 includes at least one gas supply port 13a, at least one gas diffusion chamber 13b, and a plurality of gas introducing ports 13c. The processing gas supplied to the gas supply port 13a passes through the gas diffusion chamber 13b and is introduced into the plasma processing space 10s through the plurality of gas introducing ports 13c. The shower head 13 also includes at least one upper electrode. In addition to the shower head 13, the gas introducing part may include one or a plurality of Side Gas Injectors (SGIs) attached to one or a plurality of openings formed in a side wall 10a.

The gas supply 20 may include at least one gas source 21 and at least one flow rate controller 22. In one embodiment, the gas supply 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes an RF power source 31 coupled to the plasma processing chamber 10 via at least one impedance matching circuit. The RF power source 31 is configured to supply at least one RF signal (RF power) to either or both of at least one lower electrode and at least one upper electrode. Thus, a plasma is formed from at least one processing gas supplied into the plasma processing space 10s. Therefore, the RF power source 31 can function as at least a part of the plasma forming part 12. Moreover, by supplying a bias RF signal to at least one lower electrode, which generates a bias potential in the substrate W, it is possible to attract ion components in the formed plasma into the substrate W.

In one embodiment, the RF power source 31 includes a first RF generator 31a and a second RF generator 31b. The first RF generator 31a is coupled to either or both of at least one lower electrode and at least one upper electrode via the at least one impedance matching circuit, and is configured to generate a source RF signal (source RF power) for plasma formation. In one embodiment, the source RF signal has a frequency in the range of 10 MHz to 150 MHz. In one embodiment, the first RF generator 31a may be configured to generate a plurality of source RF signals having different frequencies. The generated one or plurality of source RF signals are supplied to either or both of at least one lower electrode and at least one upper electrode.

The second RF generator 31b is coupled to at least one lower electrode via the at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or plurality of bias RF signals are supplied to at least one lower electrode. Moreover, in various embodiments, at least one of the source RF signal or the bias RF signal may be pulsed.

Also, the power source 30 may include a DC power source 32 coupled to the plasma processing chamber 10. The DC power source 32 includes a first DC generator 32a and a second DC generator 32b. In one embodiment, the first DC generator 32a is coupled to at least one lower electrode, and is configured to generate a first DC signal. The generated first DC signal is applied to at least one lower electrode. In one embodiment, the second DC generator 32b is coupled to at least one upper electrode, and is configured to generate a second DC signal. The generated second DC signal is applied to at least one upper electrode.

In various embodiments, the first and second DC signals may be pulsed. In this case, a sequence of voltage pulses is applied to either or both of at least one lower electrode and at least one upper electrode. The voltage pulses may have a rectangular, trapezoidal, or triangular pulse waveform, or a pulse waveform of any combination of these pulse waveforms. In one embodiment, a waveform generator for generating a sequence of voltage pulses from a DC signal is connected between the first DC generator 32a and at least one lower electrode. Thus, the first DC generator 32a and the waveform generator constitute a voltage pulse generator. When the second DC generator 32b and the waveform generator constitute a voltage pulse generator, the voltage pulse generator is connected to at least one upper electrode. The voltage pulses may have the positive polarity or the negative polarity. A sequence of voltage pulses may include one or a plurality of positive polarity voltage pulses and one or a plurality of negative polarity voltage pulses in one period. The first and second DC generators 32a and 32b may be provided in the RF power source 31 additionally, or the first DC generator 32a may be provided in place of the second RF generator 31b.

The gas exhaust system 40 may be connected, for example, to a gas exhaust port 10e provided on the bottom of the plasma processing chamber 10. The gas exhaust system 40 may include a pressure regulating valve and a vacuum pump. The pressure regulating valve regulates the pressure in the plasma processing space 10s. The vacuum pump may include a turbo molecular pump, a dry pump, or a combination thereof.

### <Electrostatic Chuck 1111 and Edge Ring 112A According to First Embodiment>

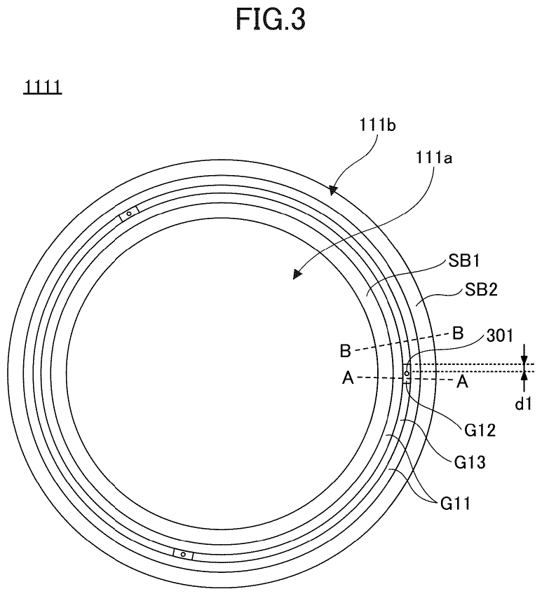

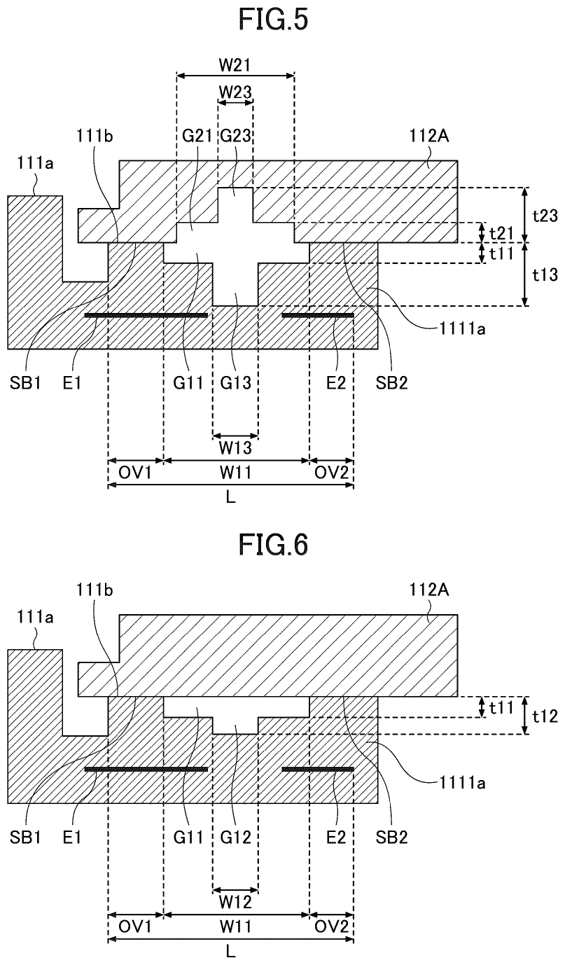

Next, the structures of the electrostatic chuck 1111 and the edge ring 112A will be described with reference to FIGS. 3 to 5. FIG. 3 is an example of a top view of the electrostatic chuck 1111. FIG. 4 is an example of a diagram schematically showing a cross-section around the edge ring 112A situated on the annular region 111b of the ceramic member 1111a according to the first embodiment, cut at a position near a heat transfer gas supply hole 301 (position A-A in FIG. 3). FIG. 5 is an example of a diagram schematically showing a cross-section around the edge ring 112A situated on the annular region 111b of the ceramic member 1111a according to the first embodiment, cut at a position apart from the heat transfer gas supply hole 301 (position B-B in FIG. 3). In FIGS. 4 and 5 (and also in FIGS. 6 to 13, which will be described later), grooves that are formed in the lower surface of the edge ring 112A and in the ring support surface of the electrostatic chuck 1111 and to which a heat transfer gas is supplied are schematically illustrated, and are scaled differently in the horizontal direction and the vertical direction.

The electrostatic chuck 1111 includes the substrate support surface (central region 111a) for supporting the substrate W and the ring support surface (annular region 111b) for supporting the ring assembly 112 (edge ring 112A).

The ring support surface (annular region 111b) includes heat transfer gas supply holes 301. A heat transfer gas (e.g., He gas and the like) is supplied to the heat transfer gas supply holes 301 from the second heat transfer gas supply. Thus, the second heat transfer gas supply supplies the heat transfer gas to the gap between the lower surface of the edge ring 112A supported on the annular region 111b and the annular region 111b of the electrostatic chuck 1111 through the heat transfer gas supply holes 301. A plurality of (three in the example of FIG. 3) heat transfer gas supply holes 301 are provided in the circumferential direction.

Grooves are formed in at least one of the lower surface of the edge ring 112A or the ring support surface of the electrostatic chuck 1111. The heat transfer gas supply holes 301 communicate with the grooves. Thus, the grooves are filled with the heat transfer gas supplied from the heat transfer gas supply holes 301. The heat transfer gas supplied from the heat transfer gas supply holes 301 is diffused in the circumferential direction and the radial direction of the edge ring 112A through the grooves formed between the lower surface of the edge ring 112A and the ring support surface of the electrostatic chuck 1111.

The annular region 111b has an inner seal band SB1 and an outer seal band SB2. The inner seal band SB1 is annularly formed on the inner side of the groove in the radial direction, and inhibits the leakage of the heat transfer gas by closely contacting the lower surface of the edge ring 112A. The outer seal band SB2 is annularly formed on the outer side of the groove in the radial direction, and inhibits the leakage of the heat transfer gas by closely contacting the lower surface of the edge ring 112A. In other words, the groove is formed between the inner seal band SB1 and the outer seal band SB2 in the radial direction of the electrostatic chuck 1111.

As shown in FIGS. 4 and 5, electrostatic electrodes E1 and E2 (corresponding to the electrostatic electrodes 111c in FIG. 2) are provided in the annular region 111b. The electrostatic electrodes E1 and E2 constitute a bipolar electrode, and one of them constitutes a positive electrode and the other constitutes a negative electrode. The edge ring 112A is clamped to the annular region 111b by the electrostatic electrodes E1 and E2.

Next, the groove formed in the lower surface of the edge ring 112A and the groove formed in the ring support surface of the electrostatic chuck 1111 will further be described.

The groove formed in the ring support surface of the electrostatic chuck 1111 include a diffusion groove G11, surrounding grooves G12 surrounding the heat transfer gas supply holes 301, and a deep groove G13. The diffusion groove G11, the surrounding grooves G12 surrounding the heat transfer gas supply holes 301, and the deep groove G13 communicate with each other.

The diffusion groove G11 is an annular groove formed between the inner seal band SB1 and the outer seal band SB2.

The surrounding grooves G12 are grooves formed around the heat transfer gas supply holes 301. Specifically, as shown in FIG. 3, the surrounding grooves G12 are each formed in a range at a distance d1 from the heat transfer gas supply hole 301. The distance d1 is, for example, 1 mm to 10 mm. The depth t1′2 of the surrounding grooves G12 is greater than the depth t11 of the diffusion groove G11 (t12>t11). The range at the distance d1 from the heat transfer gas supply hole 301 may be a range extending in the circumferential direction or in the radial direction from the heat transfer gas supply hole 301. The shape of the surrounding of the heat transfer gas supply hole 301 in which the groove is formed may be an arc shape or a rectangular shape.

The deep groove G13 is formed in an annular shape at positions except the positions at which the surrounding grooves G12 are formed. In other words, the deep groove G13 is formed of a plurality of arc-shaped grooves. The depth t13 of the deep grooves G13 is greater than the depth t11 of the diffusion groove G11 (t13>t11). The depth t13 of the deep grooves G13 is greater than the depth t12 of the surrounding grooves G12 (t13>t12).

The surrounding grooves G12 and the deep grooves G13 are formed within the range in which the diffusion groove G11 is formed in the radial direction of the electrostatic chuck 1111. That is, the radial width W11 of the diffusion groove G11 is greater than the radial width W12 of the surrounding grooves G12 (W11>W12). The radial width W11 of the diffusion groove G11 is greater than the radial width W13 of the deep grooves G13 (W11>W13). The radial width W12 of the surrounding grooves G12 and the radial width W13 of the deep grooves G13 may be the same (W12=W13) or may be different.

In the circumferential direction of the electrostatic chuck 1111, in the annular region including the positions at which the heat transfer gas supply holes 301 are formed, the surrounding grooves G12 are formed in the regions around the heat transfer gas supply holes 301, and the deep grooves G13 are formed in the regions other than the regions around the heat transfer gas supply holes 301. In this annular region, the surrounding grooves G12 and the deep grooves G13 are formed alternately. In addition, the diffusion groove G11 is formed on the inner side of the annular region in the radial direction. Moreover, the diffusion groove G11 is formed on the outer side of the annular region in the radial direction as well.

Namely, the annular region 111b of the electrostatic chuck 1111 includes, from the inner peripheral side, the inner seal band SB1, the inner peripheral side of the diffusion groove G11, the region in which the surrounding grooves G12 and the deep grooves G13 are formed alternately, the outer peripheral side of the diffusion groove G11, and the outer seal band SB2.

Grooves formed in the lower surface of the edge ring 112A include a diffusion groove G21, surrounding grooves G22 formed at the positions corresponding to the heat transfer gas supply holes 301, and deep groove G23. The diffusion groove G21, the surrounding grooves G22, and the deep grooves G23 communicate with each other.

The diffusion groove G21 is an annular groove formed between the inner seal band SB1 and the outer seal band SB2. In other words, the diffusion groove G21 is an annular groove formed between an inner back surface of the edge ring 112A including a region contacting the inner seal band SB1, and an outer back surface of the edge ring 112A including a region contacting the outer seal band SB2.

The surrounding grooves G22 are grooves formed around the positions corresponding to the heat transfer gas supply holes 301. The depth t22 of the surrounding grooves G22 is greater than the depth t21 of the diffusion groove G21 (t22>t21).

The deep grooves G23 are formed in an annular shape at positions except the positions at which the surrounding grooves G22 are formed. In other words, the deep grooves G23 are a plurality of arc-shaped grooves. The depth t23 of the deep grooves G23 is greater than the depth t21 of the diffusion groove G21 (t23>t21). The depth t23 of the deep grooves G23 may be greater than the depth t22 of the surrounding grooves G22 (t23>t22).

The surrounding grooves G22 and the deep grooves G23 are formed within the range in which the diffusion groove G21 is formed in the radial direction of the edge ring 112A. That is, the radial width W21 of the diffusion groove G21 is greater than the radial width W22 of the surrounding grooves G22 (W21>W22). The radial width W21 of the diffusion groove G21 is greater than the radial width W23 of the deep grooves G23 (W21>W23). The radial width W22 of the surrounding grooves G22 and the radial width W23 of the deep grooves G23 may be the same (W22=W23) or may be different.

In the circumferential direction of the edge ring 112A, the surrounding grooves G22 and the deep grooves G23 are formed in the annular region including the positions at which the heat transfer gas supply holes 301 are formed. In this annular region, the surrounding grooves G22 and the deep grooves G23 are formed alternately. The diffusion groove G21 is formed on the inner side of the annular region in the radial direction. The diffusion groove G21 is formed on the outer side of the annular region in the radial direction as well.

That is, the lower surface of the edge ring 112A includes, from the inner peripheral side, the inner back surface of the edge ring 112A including the region contacting the inner seal band SB1, the inner peripheral side of the diffusion groove G21, the region in which the surrounding grooves G22 and the deep grooves G23 are formed alternately, the outer peripheral side of the diffusion groove G21, and the outer back surface of the edge ring 112A including the region contacting the outer seal band SB2.

That is, in a state in which the edge ring 112A is supported on the annular region 111b of the electrostatic chuck 1111 and is clamped, a space (third space) having a depth t11+t21 is formed by the diffusion groove G11 and the diffusion groove G21 (see FIGS. 4 and 5), a space (first space) having a depth t12+t22 is formed by the surrounding grooves G12 and G22 (see FIG. 4), and a space (second space) having a depth t13+t23 is formed by the deep grooves G13 and G23 (see FIG. 5).

In other words, in a state in which the edge ring 112A is supported on the annular region 111b of the electrostatic chuck 1111, the first space (surrounding grooves G12, and surrounding grooves G22) communicating with the heat transfer gas supply holes 301, the second space (deep grooves G13, and deep grooves G23) communicating with the first space and formed in the circumferential direction, and the third space (diffusion groove G11, and diffusion groove G21) communicating with the first space and the second space and formed in the radial direction are provided by the grooves formed in either or both of the lower surface of the edge ring 112A and the ring support surface of the electrostatic chuck 1111. In other words, a plurality of first spaces (surrounding grooves G12, and surrounding grooves G22) communicating with the heat transfer gas supply holes 301 respectively, arc-shaped second spaces (deep grooves G13, and deep grooves G23) communicating one first space with another first space adjacent to the one first space in the circumferential direction and formed in the circumferential direction, and the third space (diffusion groove G11, and diffusion groove G21) communicating with the first spaces and the second spaces and formed in the radial direction are provided. The height of the second spaces is greater than the height of the first spaces. The height of the third space is less than the height of the first spaces and less than the height of the second spaces.

With this configuration, the heat transfer gas discharged from the heat transfer gas supply holes 301 is discharged to the first spaces. As the heat transfer gas flows from the first spaces to the second spaces, the heat transfer gas diffuses in the circumferential direction. As the heat transfer gas flows from the first spaces and the second spaces to the third space, the heat transfer gas diffuses in the radial direction. Thus, the heat transfer gas supplied from the heat transfer gas supply holes 301 provided separately from each other into the space between the ring support surface of the electrostatic chuck 1111 and the lower surface of the edge ring 112A can be diffused in the circumferential direction and the radial direction.

That is, with the height (t13+t23) of the spaces (second spaces) formed by the deep grooves G13 and the deep grooves G23 set to be greater than that of the other spaces (first spaces, and third space), the diffusion of the heat transfer gas in the circumferential direction is promoted.

With the height (t11+t21) of the space (third space) formed by the diffusion groove G11 and the diffusion groove G21 set to be less than that of the other spaces (first spaces, and second spaces), the distance between the electrostatic chuck 1111 and the edge ring 112A is shortened and the heat transfer between the electrostatic chuck 1111 and the edge ring 112A is improved.

The height (t12+t22) of the spaces (first spaces) formed by the surrounding grooves G12 and the surrounding grooves G22 is set to be less than the height (t13+t23) of the spaces (second spaces) formed by the deep grooves G13 and the deep grooves G23. Thus, restricting the height of the spaces (first spaces) around the heat transfer gas supply holes 301 inhibits acceleration of electrons, thereby preventing or inhibiting occurrence of an abnormal discharge around the heat transfer gas supply holes 301. In the second spaces and the third space, a dielectric material (ceramic member 1111a) is situated between the edge ring 112A and the electrostatic electrodes 111c (E1, E2). Thus, the potential difference between the top surface and the bottom surface of the second spaces and the third space can be reduced, preventing occurrence of an abnormal discharge.

Although the depth t23 of the deep grooves G23 of the edge ring 112A has been described as being greater than the depth t22 of the surrounding grooves G22 of the edge ring 112A, this is non-limiting. The height (t13+t23) of the spaces (second spaces) formed by the deep grooves G13 and the deep grooves G23 need only be greater than the height (t12+t22) of the spaces (first spaces) formed by the surrounding grooves G12 and the surrounding grooves G22. For example, the depth t23 of the deep grooves G23 of the edge ring 112A and the depth t22 of the surrounding grooves G22 of the edge ring 112A may be the same.

An example of the values of the width dimension of the grooves is shown below.

Width W11 of the groove G11: for example, 1 mm to 38 mm
Width W12 of the grooves G12: for example, 0.5 mm to 38 mm (where W11>W12)
Width W13 of the grooves G13: for example, 0.5 mm to 38 mm (where W11>W13)
Width W21 of the groove G21: for example, 1 mm to 38 mm
Width W22 of the grooves G22: for example, 0.5 mm to 38 mm (where W21>W22)
Width W23 of the grooves G23: for example, 0.5 mm to 38 mm (where W21>W23)

Note that the width W1l and the width W21 may be the same or may be different. The width W12 and the width W22 may be the same or may be different. The width W13 and the width W23 may be the same or may be different. The width W12 and the width W13 may be the same or may be different. The width W22 and the width W23 may be the same or may be different.

An example of the values of the depth dimension of the grooves (height of the spaces) is shown below.
Height (t12+t22) of the first spaces: for example, 2 μm to 40 μm
Height (t13+t23) of the second spaces: for example, 2 μm to 200 μm
Height (t11+t21) of the third space: for example, 1 μm to 25 μm

In this embodiment, the depth of each groove described above may be varied in the circumferential direction.

In the radial direction, the overlap distance OV1 by which the electrostatic electrode E1 and the inner seal band SB1 overlap is, for example, 1 mm to 15 mm. The overlap distance OV2 by which the electrostatic electrode E2 and the outer seal band SB2 overlap is, for example, 1 mm to 15 mm. The overlap distance OV1 and the overlap distance OV2 may be the same or may be different.

In the region where the seal band SB1 (SB2) and the electrostatic electrode E1 (E2) overlap, the edge ring 112A and the electrostatic chuck 1111 are brought into close contact by an electrostatic attraction force. Thus, leakage of the heat transfer gas from the space between the ring support surface of the electrostatic chuck 1111 and the lower surface of the edge ring 112A is inhibited. That is, the overlap distances OV1 and OV2 are values related to the sealing performance.

In the radial direction, the distance L, which is the difference between “the smaller diameter of the outer diameter of the electrostatic electrode E2 and the outer diameter of the seal band SB2” and “the larger diameter of the inner diameter of the electrostatic electrode E1 and the inner diameter of the seal band SB1”, is, for example, 3 mm to 40 mm.

The distance L is the distance from the position of the innermost inner diameter to the position of the outermost inner diameter between which the edge ring 112A and the electrostatic chuck 1111 have close contact with each other owing to the electrostatic attraction force.

### <Electrostatic Chuck 1111 and Edge Ring 112A According to Second Embodiment>

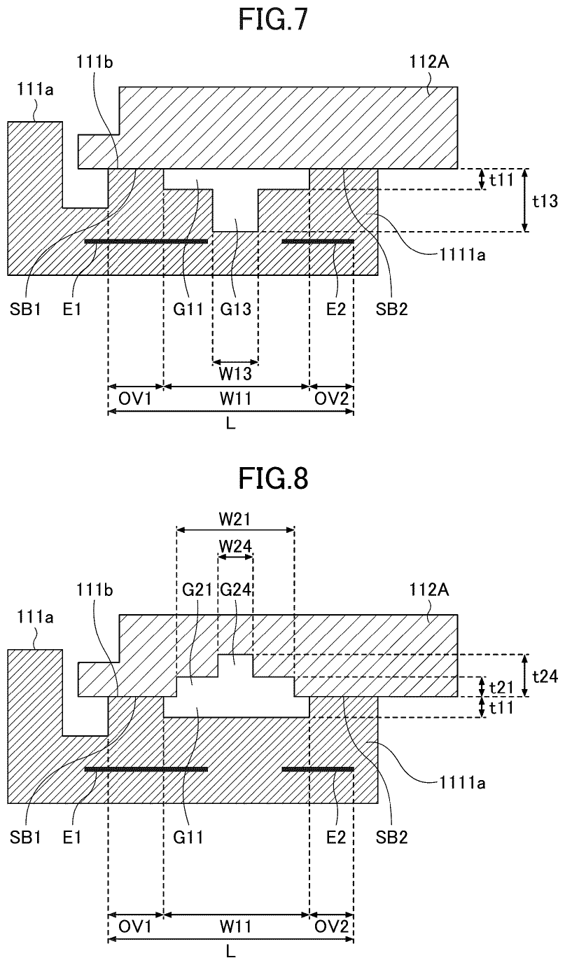

Next, another structure of the electrostatic chuck 1111 and the edge ring 112A will be described with reference to FIGS. 6 to 7. FIG. 6 is an example of a diagram schematically showing a cross-section around the edge ring 112A situated on the annular region 111b of the ceramic member 1111a according to the second embodiment, cut at a position near a heat transfer gas supply hole 301. FIG. 7 is an example of a diagram schematically showing a cross-section around the edge ring 112A situated on the annular region 111b of the ceramic member 1111a according to the second embodiment, cut at a position apart from the heat transfer gas supply hole 301. Descriptions that overlap the first embodiment (see FIGS. 3 to 5) will be omitted.

No groove is formed in the lower surface of the edge ring 112A, and grooves are formed in the ring support surface of the electrostatic chuck 1111. The grooves formed in the ring support surface of the electrostatic chuck 1111 include a diffusion groove G11, surrounding grooves G12 surrounding the heat transfer gas supply holes 301, and deep grooves G13. The diffusion groove G11, the surrounding grooves G12 surrounding the heat transfer gas supply holes 301, and the deep grooves G13 communicate with each other.

In a state in which the edge ring 112A is supported on the annular region 111b of the electrostatic chuck 1111, first spaces (surrounding grooves G12) that communicates with the heat transfer gas supply holes 301, second spaces (deep grooves G13) that communicate with the first spaces and are formed in the circumferential direction, and a third space (diffusion groove G11) that communicates with the first spaces and the second spaces and is formed in the radial direction are provided by the lower surface of the edge ring 112A and by the grooves formed in the ring support surface of the electrostatic chuck 1111. The height of the second spaces is greater than the height of the first spaces. The height of the third space is less than the height of the first spaces and less than the height of the second spaces.

With this configuration, the heat transfer gas discharged from the heat transfer gas supply holes 301 is first discharged into the spaces (first spaces) formed by the surrounding grooves G12. Then, as the heat transfer gas flows from the spaces (first spaces) formed by the surrounding grooves G12 to the spaces (second spaces) formed by the deep grooves G13, the heat transfer gas diffuses in the circumferential direction. As the heat transfer gas flows from the spaces (first spaces) formed by the surrounding grooves G12 and the spaces (second spaces) formed by the deep grooves G13 to the space (third space) formed by the diffusion groove G11, the heat transfer gas diffuses in the radial direction. Thus, the heat transfer gas supplied from the heat transfer gas supply holes 301 provided separately from each other into the space between the ring support surface of the electrostatic chuck 1111 and the lower surface of the edge ring 112A can be diffused in the circumferential direction and the radial direction.

That is, with the height (t13) of the second spaces set to be greater than that of the other spaces (first spaces, and third space), the diffusion of the heat transfer gas in the circumferential direction is promoted.

With the height (t11) of the third space set to be less than the height of the other spaces (first spaces, and second spaces), the distance between the electrostatic chuck 1111 and the edge ring 112A is shortened, and the heat transfer between the electrostatic chuck 1111 and the edge ring 112A is improved.

The height (t12) of the first spaces is set to be less than the height (t13) of the second spaces. Thus, restricting the height of the spaces around the heat transfer gas supply holes 301 inhibits acceleration of electrons, thereby preventing or inhibiting occurrence of an abnormal discharge around the heat transfer gas supply holes 301.

An example of the values of the depth dimension of the grooves (height of the spaces) is shown below.
Height (t12) of the first spaces: for example, 2 μm to 40 μm
Height (t13) of the second spaces: for example, 2 μm to 200 μm
Height (t11) of the third space: for example, 1 μm to 25 μm

In this embodiment, the depth of each groove described above may be varied in the circumferential direction.

### <Electrostatic Chuck 1111 and Edge Ring 112A According to Third Embodiment>

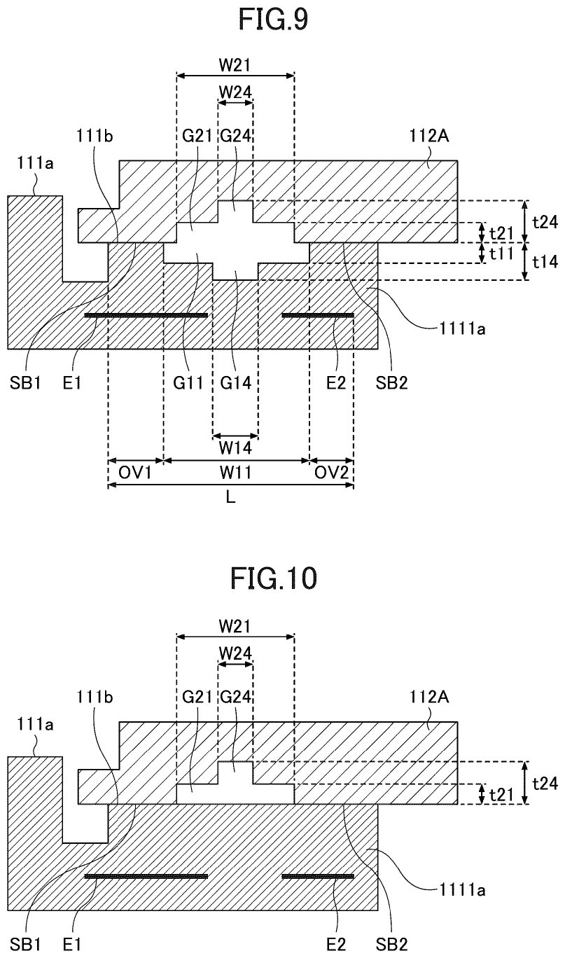

Next, another structure of the electrostatic chuck 1111 and the edge ring 112A will be described with reference to FIGS. 8 to 9. FIG. 8 is an example of a diagram schematically showing a cross-section around the edge ring 112A situated on the annular region 111b of the ceramic member 1111a according to the third embodiment, cut at a position near a heat transfer gas supply hole 301. FIG. 9 is an example of a diagram schematically showing a cross-section around the edge ring 112A situated on the annular region 111b of the ceramic member 1111a according to the third embodiment, cut at a position apart from the heat transfer gas supply hole 301. Descriptions that overlap the first embodiment (see FIGS. 3 to 5) will be omitted.

Grooves are formed in the lower surface of the edge ring 112A and in the ring support surface of the electrostatic chuck 1111.

The grooves formed in the ring support surface of the electrostatic chuck 1111 include a diffusion groove G11 and deep grooves G14. The diffusion groove G11 and the deep grooves G14 communicate with each other. Here, the depth of the surrounding grooves G12 (see FIG. 4) is the same as the depth t11 of the diffusion groove G11.

The deep grooves G14 are formed in an annular shape at positions except the surroundings of where the heat transfer gas supply holes 301 are formed. In other words, the deep grooves G14 are formed of a plurality of arc-shaped grooves. The depth t14 of the deep grooves G14 is greater than the depth t11 of the diffusion groove G11 (t14>t11).

In the radial direction of the electrostatic chuck 1111, the deep grooves G14 are formed within the range in which the diffusion groove G11 is formed. That is, the radial width W11 of the diffusion groove G11 is greater than the radial width W14 of the deep groove G14 (W11>W14).

The grooves formed in the lower surface of the edge ring 112A include a diffusion groove G21 and deep grooves G24. The diffusion groove G21 and the deep grooves G24 communicate with each other. Here, the depth of the surrounding grooves G22 (see FIG. 4) is the same as the depth of the deep grooves G23 (see FIG. 4), which are formed as the deep grooves G24 having an annular shape.

The deep grooves G24 are grooves formed in an annular shape. The depth t24 of the deep grooves G24 is greater than the depth t21 of the diffusion groove G21 (t24>t21).

In the radial direction of the edge ring 112A, the deep grooves G24 are formed within the range in which the diffusion groove G21 is formed. That is, the radial width W21 of the diffusion groove G21 is greater than the radial width W24 of the deep grooves G24 (W21>W24).

In a state in which the edge ring 112A is supported on the annular region 111b of the electrostatic chuck 1111, first spaces (diffusion groove G11, and deep grooves G24) communicating with the heat transfer gas supply holes 301, second spaces (deep grooves G14, and deep grooves G24) communicating with the first spaces and formed in the circumferential direction, and a third space (diffusion groove G11, and diffusion groove G21) communicating with the first spaces and the second spaces and formed in the radial direction are provided by the grooves formed in the lower surface of the edge ring 112A and by the grooves formed in the ring support surface of the electrostatic chuck 1111. The height of the second spaces is greater than the height of the first spaces. The height of the third space is less than the height of the first spaces and less than the height of the second spaces.

With this configuration, the heat transfer gas discharged from the heat transfer gas supply holes 301 is discharged into the first spaces. As the heat transfer gas flows from the first spaces to the second spaces, the heat transfer gas diffuses in the circumferential direction. As the heat transfer gas flows from the first spaces and the second spaces to the third space, the heat transfer gas diffuses in the radial direction. Thus, the heat transfer gas supplied from the heat transfer gas supply holes 301 provided separately from each other into the space between the ring support surface of the electrostatic chuck 1111 and the lower surface of the edge ring 112A can be diffused in the circumferential direction and the radial direction.

That is, with the height (t14+t24) of the second spaces set to be greater than the other spaces (first spaces, and third space), the diffusion of the heat transfer gas in the circumferential direction is promoted.

Further, with the height (t11+t21) of the third space set to be less than the height of the other spaces (first spaces, and second spaces), the distance between the electrostatic chuck 1111 and the edge ring 112A is shortened, and the heat transfer between the electrostatic chuck 1111 and the edge ring 112A is improved.

Moreover, the height (t11+t24) of the first spaces is set to be less than the height (t14+t24) of the second spaces. Thus, restricting the height of the spaces around the heat transfer gas supply holes 301 inhibits acceleration of electrons, thereby preventing or inhibiting occurrence of an abnormal discharge around the heat transfer gas supply holes 301.

An example of the values of the width dimension of the grooves is shown below.
Width W11 of the groove G11: for example, 1 mm to 38 mm
Width W14 of the grooves G14: for example, 0.5 mm to 38 mm (where W11>W14)
Width W21 of the groove G21: for example, 1 mm to 38 mm
Width W24 of the grooves G24: for example, 0.5 mm to 38 mm (where W21>W24)

The width W11 and the width W21 may be the same or may be different. The width W14 and the width W24 may be the same or may be different.

An example of the values of the depth dimension of the grooves (height of the spaces) is shown below.
Height (t11+t24) of the first spaces: for example, 2 μm to 40 μm
Height (t14+t24) of the second spaces: for example, 2 μm to 200 μm
Height (t11+t21) of the third space: for example, 1 μm to 25 μm

The depth of each groove in this embodiment may be varied in the circumferential direction.

### <Electrostatic Chuck 1111 and Edge Ring 112A According to Fourth Embodiment>

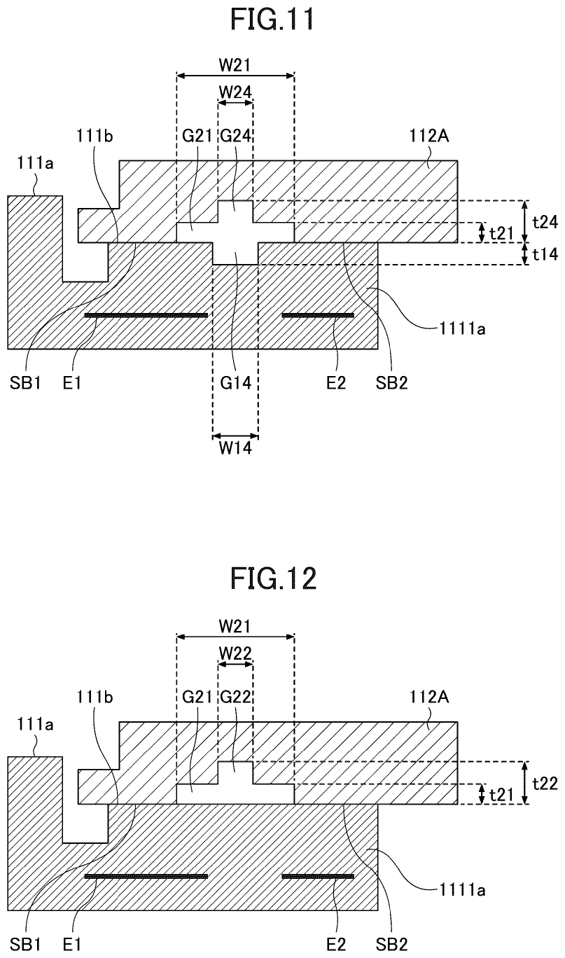

Next, another structure of the electrostatic chuck 1111 and the edge ring 112A will be described with reference to FIGS. 10 to 11. FIG. 10 is an example of a diagram schematically showing a cross-section around the edge ring 112A situated on the annular region 111b of the ceramic member 1111a according to the fourth embodiment, cut at a position near a heat transfer gas supply hole 301. FIG. 11 is an example of a diagram schematically showing a cross-section around the edge ring 112A situated on the annular region 111b of the ceramic member 1111a according to the fourth embodiment, cut at a position apart from the heat transfer gas supply hole 301. Descriptions that overlap the first embodiment (see FIGS. 3 to 5) will be omitted.

Grooves are formed in the lower surface of the edge ring 112A and the ring support surface of the electrostatic chuck 1111.

The grooves formed in the ring support surface of the electrostatic chuck 1111 includes deep grooves G14. Here, the heat transfer gas supply holes 301 are formed in the ring support surface of the electrostatic chuck 1111.

The deep grooves G14 are grooves formed in an annular shape at positions except the surroundings of where the heat transfer gas supply holes 301 are formed. In other words, the deep grooves G14 are formed of a plurality of arc-shaped grooves.

In the radial direction of the edge ring 112A, deep grooves G24 are formed within the range in which a diffusion groove G21 is formed. That is, the radial width W21 of the diffusion groove G21 is greater than the radial width W24 of the deep grooves G24 (W21>W24).

The diffusion groove G21 and the deep grooves G24 communicate with each other.

In a state in which the edge ring 112A is supported on the annular region 111b of the electrostatic chuck 1111, first spaces (deep grooves G24) communicating with the heat transfer gas supply holes 301, second spaces (deep grooves G14, and deep grooves G24) communicating with the first spaces and formed in the circumferential direction, and a third space (diffusion groove G21) communicating with the first spaces and the second spaces and formed in the radial direction are provided by the grooves formed in the lower surface of the edge ring 112A and by the groove formed in the ring support surface of the electrostatic chuck 1111. The height of the second spaces is greater than the height of the first spaces. The height of the third space is less than the height of the first spaces and less than the height of the second spaces.

With this configuration, the heat transfer gas discharged from the heat transfer gas supply holes 301 is discharged into the first spaces. As the heat transfer gas flows from the first spaces to the second spaces, the heat transfer gas diffuses in the circumferential direction. As the heat transfer gas flows from the first spaces and the second spaces to the third space, the heat transfer gas diffuses in the radial direction. Thus, the heat transfer gas supplied from the heat transfer gas supply holes 301 provided separately into the space between the ring support surface of the electrostatic chuck 1111 and the lower surface of the edge ring 112A can be diffused in the circumferential direction and the radial direction.

That is, with the height (t14+t24) of the second spaces set to be greater than the other spaces (first spaces, and third space), the diffusion of the heat transfer gas in the circumferential direction is promoted.

Moreover, with the height (t21) of the third space set to be less than the height of the other spaces (first spaces, and second spaces), the distance between the electrostatic chuck 1111 and the edge ring 112A is shortened, and the heat transfer between the electrostatic chuck 1111 and the edge ring 112A is improved.

Moreover, the height (t24) of the first spaces is set to be less than the height (t14+t24) of the second spaces. Thus, restricting the height of the spaces around the heat transfer gas supply holes 301 inhibits acceleration of electrons, thereby preventing or inhibiting occurrence of an abnormal discharge around the heat transfer gas supply holes 301.

An example of the values of the depth dimension of the grooves (height of the spaces) is shown below.
Height (t24) of the first spaces: for example, 2 μm to 40 μm
Height (t14+t24) of the second spaces: for example, 2 μm to 200 μm
Height (t21) of the third space: for example, 1 μm to 25 μm

The depth of each groove in this embodiment may be varied in the circumferential direction.

### <Electrostatic Chuck 1111 and Edge Ring 112A According to Fifth Embodiment>

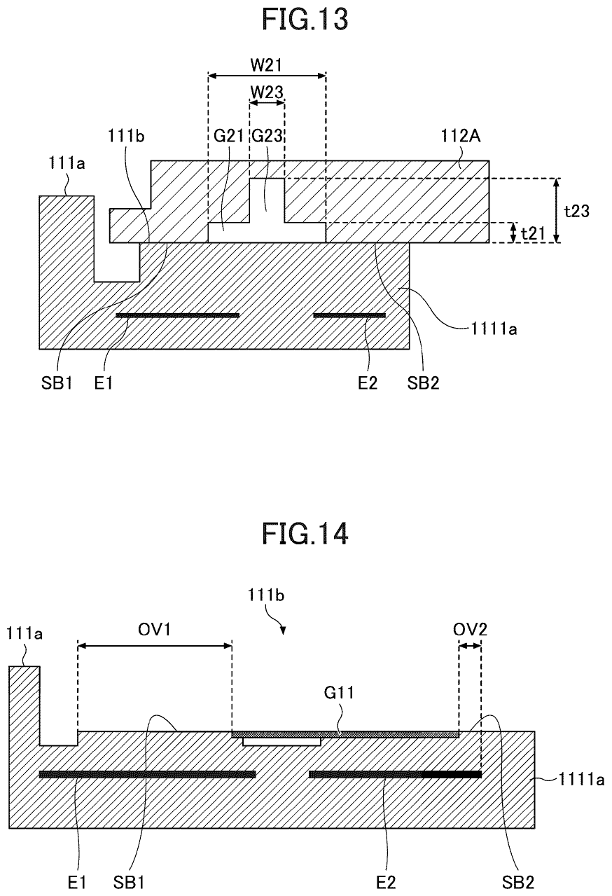

Next, another structure of the electrostatic chuck 1111 and the edge ring 112A will be described with reference to FIGS. 12 to 13. FIG. 12 is an example of a diagram schematically showing a cross-section around the edge ring 112A situated on the annular region 111b of the ceramic member 1111a according to the fifth embodiment, cut at a position near a heat transfer gas supply hole 301. FIG. 13 is an example of a diagram schematically showing a cross-section around the edge ring 112A situated on the annular region 111b of the ceramic member 1111a according to the fifth embodiment, cut at a position apart from the heat transfer gas supply hole 301. Descriptions that overlap the first embodiment (see FIGS. 3 to 5) will be omitted.

No groove is formed in the ring support surface of the electrostatic chuck 1111, and grooves are formed in the lower surface of the edge ring 112A. The grooves formed in the lower surface of the edge ring 112A include a diffusion groove G21, surrounding grooves G22 formed at the positions corresponding to the heat transfer gas supply holes 301, and deep grooves G23. The diffusion groove G21, the surrounding grooves G22, and the deep grooves G23 communicate with each other.

In a state in which the edge ring 112A is supported on the annular region 111b of the electrostatic chuck 1111, first spaces (surrounding grooves G22) communicating with the heat transfer gas supply holes 301, second spaces (deep grooves G23) communicating with the first spaces and formed in the circumferential direction, and a third space (diffusion groove G21) communicating with the first spaces and the second spaces and formed in the radial direction are provided by the grooves formed in the lower surface of the edge ring 112A and by the ring support surface of the electrostatic chuck 1111. The height of the second spaces is greater than the height of the first spaces. The height of the third space is less than the height of the first spaces and less than the height of the second spaces.

With this configuration, the heat transfer gas discharged from the heat transfer gas supply holes 301 is discharged into the first spaces. As the heat transfer gas flows from the first spaces to the second spaces, the heat transfer gas diffuses in the circumferential direction. As the heat transfer gas flows from the first spaces and the second spaces to the third space, the heat transfer gas diffuses in the radial direction. Thus, the heat transfer gas supplied from the heat transfer gas supply holes 301 provided separately into the space between the ring support surface of the electrostatic chuck 1111 and the lower surface of the edge ring 112A can be diffused in the circumferential direction and the radial direction.

That is, with the height (t23) of the second spaces set to be greater than that of the other spaces (first spaces, and third space), the diffusion of the heat transfer gas in the circumferential direction is promoted.

With the height (t21) of the third space set to be less than the height of the other spaces (first spaces and second spaces), the distance between the electrostatic chuck 1111 and the edge ring 112A is shortened, and the heat transfer between the electrostatic chuck 1111 and the edge ring 112A is improved.

The height (t22) of the first spaces is set to be less than the height (t23) of the second spaces. Thus, restricting the height of the spaces around the heat transfer gas supply holes 301 inhibits acceleration of electrons, thereby preventing or inhibiting occurrence of an abnormal discharge around the heat transfer gas supply holes 301.

An example of the values of the depth dimension of the grooves (height of the spaces) is shown below.
Height (t22) of the first spaces: for example, 2 μm to 40 μm
Height (t23) of the second spaces: for example, 2 μm to 200 μm
Height (t21) of the third space: for example, 1 μm to 25 μm

The depth of each groove in this embodiment may be varied in the circumferential direction.

### <Seal Distance>

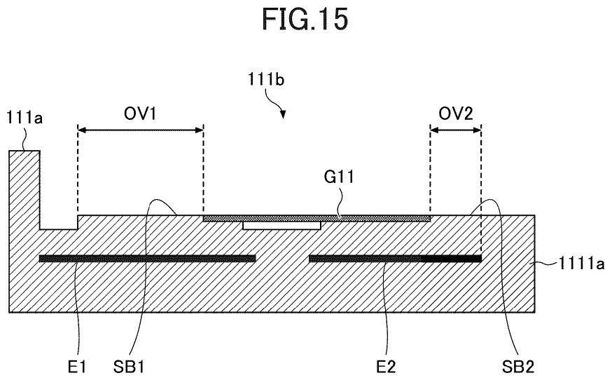

Next, the seal distance in the inner seal band SB1 and the outer seal band SB2 will be described with reference to FIGS. 14 and 15. FIG. 14 is an example of a diagram schematically showing a cross-section of the ceramic member 1111a in which grooves are formed. FIG. 15 is an example of a diagram schematically showing a cross-section of the ceramic member 1111a in which grooves are formed.

With the width W11 of the diffusion groove G11 (see FIG. 4 and the like) maintained, the position at which the diffusion groove G11 is formed may be shifted in the radial direction of the electrostatic chuck 1111. This makes it possible to adjust the ratio between the seal distance OV1 in the inner seal band SB1 and the seal distance OV2 in the outer seal band SB2.

For example, leakage of the heat transfer gas occurs from the side at which the seal distance is shorter (the outer peripheral side in the example of FIG. 14). Shifting the position at which the diffusion groove G11 is formed to the inner peripheral side can increase the seal distance OV2 on the outer peripheral side as shown in FIG. 15. Thus, leakage of the heat transfer gas can be inhibited.

When occurrence of leakage of the heat transfer gas on the inner peripheral side near the substrate W has the risk of affecting the process, shifting the position at which the diffusion groove G11 is formed to the outer peripheral side can increase the seal distance OV1 on the inner peripheral side as shown in FIG. 14. Thus, it is possible to inhibit occurrence of leakage of the heat transfer gas on the inner peripheral side.

The embodiments disclosed above include, for example, the following aspects.

### Clause 1

A substrate processing apparatus, including:
a plasma processing chamber;
a base table situated in the plasma processing chamber;
an electrostatic chuck situated on the base table and having a substrate support surface and a ring support surface; and
an edge ring situated on the ring support surface;
wherein a groove in which a heat transfer gas is diffused is formed in at least one of the ring support surface or a lower surface of the edge ring,
wherein a heat transfer gas supply hole, configured to supply the transfer gas into the groove, is formed in the ring support surface, and
wherein in an annular region including a position at which the heat transfer gas supply hole is formed, a depth of the groove in a surrounding region around the heat transfer gas supply hole is less than a depth of the groove in a region other than the surrounding region.

### Clause 2

The substrate processing apparatus according to Clause 1,
wherein the groove includes a diffusion groove on an inner side of the annular region in a radial direction and on an outer side of the annular region in the radial direction.

### Clause 3

The substrate processing apparatus according to Clause 1 or 2,
wherein the groove forms a space between the ring support surface and the lower surface of the edge ring, and
the space includes:
   a first space communicating with the heat transfer gas supply hole;
   a second space communicating with the first space and formed in a circumferential direction; and
   a third space communicating with the first space and the second space and formed in a radial direction.

### Clause 4

The substrate processing apparatus according to Clause 3,
wherein a height of the second space is greater than a height of the first space, and
wherein a height of the third space is less than the height of the first space.

### Clause 5

The substrate processing apparatus according to any of Clauses 1 to 4,
wherein the ring support surface includes:
a first surrounding groove formed around the heat transfer gas supply hole;
a first deep groove communicating with the first surrounding groove and formed in a circumferential direction; and
a first diffusion groove communicating with the first surrounding groove and the first deep groove and formed in a radial direction,
wherein the lower surface of the edge ring includes:
a second surrounding groove formed around a position corresponding to the heat transfer gas supply hole;
a second deep groove communicating with the second surrounding groove and formed in the circumferential direction; and
a second diffusion groove communicating with the second surrounding groove and the second deep groove and formed in the radial direction, and
wherein a height of a space formed by the first deep groove and the second deep groove is greater than a height of a space formed by the first surrounding groove and the second surrounding groove.

### Clause 6

The substrate processing apparatus according to any one of Clauses 1 to 4,
wherein the ring support surface includes:
a surrounding groove formed around the heat transfer gas supply hole;
a deep groove communicating with the surrounding groove and formed in a circumferential direction; and
a diffusion groove communicating with the surrounding groove and the deep groove and formed in a radial direction, and
wherein a depth of the deep groove is greater than a depth of the surrounding groove.

### Clause 7

A substrate processing apparatus according to any of Clauses 1 to 4,
wherein the ring support surface includes:
a first diffusion groove formed in a radial direction; and
a first deep groove formed in a circumferential direction in a region other than the surrounding region around the heat transfer gas supply hole,
wherein the lower surface of the edge ring includes:
a second diffusion groove formed in the radial direction; and
a second deep groove formed in an annular shape, and
wherein a height of a space formed by the first deep groove and the second deep groove is greater than a height of a space formed by the first diffusion groove and the second diffusion groove.

### Clause 8

The substrate processing apparatus according to any one of Clauses 1 to 4,
wherein a first deep groove formed in a circumferential direction is formed in the ring support surface in a region other than the surrounding region around the heat transfer gas supply hole,
wherein the lower surface of the edge ring includes:
a second diffusion groove formed in a radial direction; and
a second deep groove formed in an annular shape, and
wherein a height of a space formed by the first deep groove and the second deep groove is greater than a height of a space formed by the second diffusion groove.

### Clause 9

The substrate processing apparatus according to any one of Clauses 1 to 4,
wherein the lower surface of the edge ring includes:
a surrounding groove formed around a position corresponding to the heat transfer gas supply hole;
a deep groove communicating with the surrounding groove and formed in a circumferential direction; and
a diffusion groove communicating with the surrounding groove and the deep groove and formed in a radial direction, and
wherein a depth of the deep groove is greater than a depth of the surrounding groove.

### Clause 10

The substrate processing apparatus according to any of Clauses 1 to 9,
wherein the electrostatic chuck includes an electrostatic electrode situated in a ceramic member and configured to clamp the edge ring.

### Clause 11

The substrate processing apparatus according to Clause 10,
wherein the electrostatic chuck includes an inner seal band on an inner side of the groove in a radial direction and an outer seal band on an outer side of the groove in the radial direction,
wherein the electrostatic electrode includes a first electrostatic electrode and a second electrostatic electrode situated on an outer side of the first electrostatic electrode in the radial direction, and
wherein in the radial direction, the inner seal band and the first electrostatic electrode overlap at least partially, and the outer seal band and the second electrostatic electrode overlap at least partially.

### Clause 12

The substrate processing apparatus according to Clause 4,
wherein the height of the first space is in a range of 2 μm to 40 μm,
wherein the height of the second space is in a range of 2 μm to 200 ppm, and
wherein the height of the third space is in a range of 1 μm to 25 μm.

### Clause 13

The substrate processing apparatus according to any of Clauses 1 to 11,
wherein the surrounding region around the heat transfer gas supply hole is in a range of 1 mm to 10 mm from an outer periphery of the heat transfer gas supply hole in a circumferential direction.

### Clause 14

An electrostatic chuck, including:
a substrate support surface configured to support a substrate; and
a ring support surface configured to support an edge ring,
wherein a groove in which a heat transfer gas is diffused is formed in the ring support surface,
wherein a heat transfer gas supply hole configured to supply the heat transfer gas into the groove is formed, and
wherein in an annular region including a position at which the heat transfer gas supply hole is formed, a depth of the groove in a surrounding region around the heat transfer gas supply hole is less than a depth of the groove in a region other than the surrounding region.

According to one aspect, it is possible to provide a substrate processing apparatus and an electrostatic chuck for preventing or inhibiting occurrence of an abnormal discharge at a lower part of an edge ring.

It should be noted that the present disclosure is not limited to the configurations shown here, such as the configurations presented in the embodiments described above, combinations with other elements, and the like. These particulars can be modified within a range not departing from the spirit of the present disclosure, and can be appropriately defined in accordance with how they are applied.

What is claimed is:

1. A substrate processing apparatus, comprising:
a plasma processing chamber;
a base table situated in the plasma processing chamber;
an electrostatic chuck situated on the base table and having a substrate support surface and a ring support surface; and
an edge ring situated on the ring support surface,
wherein a groove in which a heat transfer gas is diffused is formed in at least one of the ring support surface or a lower surface of the edge ring,
wherein a heat transfer gas supply hole, configured to supply the transfer gas into the groove, is formed in the ring support surface, and
wherein in an annular region including a position at which the heat transfer gas supply hole is formed, a depth of the groove in a surrounding region around the heat transfer gas supply hole is less than a depth of the groove in a region other than the surrounding region.

2. The substrate processing apparatus according to claim 1,
wherein the groove includes a diffusion groove on an inner side of the annular region in a radial direction and on an outer side of the annular region in the radial direction.

3. The substrate processing apparatus according to claim 1,
wherein the groove forms a space between the ring support surface and the lower surface of the edge ring, and
the space includes:
a first space communicating with the heat transfer gas supply hole;
a second space communicating with the first space and formed in a circumferential direction; and
a third space communicating with the first space and the second space and formed in a radial direction.

4. The substrate processing apparatus according to claim 3,
wherein a height of the second space is greater than a height of the first space, and
wherein a height of the third space is less than the height of the first space.

5. The substrate processing apparatus according to claim 1,
wherein the ring support surface includes:
a first surrounding groove formed around the heat transfer gas supply hole;
a first deep groove communicating with the first surrounding groove and formed in a circumferential direction; and
a first diffusion groove communicating with the first surrounding groove and the first deep groove and formed in a radial direction,
wherein the lower surface of the edge ring includes:
a second surrounding groove formed around a position corresponding to the heat transfer gas supply hole;
a second deep groove communicating with the second surrounding groove and formed in the circumferential direction; and
a second diffusion groove communicating with the second surrounding groove and the second deep groove and formed in the radial direction, and
wherein a height of a space formed by the first deep groove and the second deep groove is greater than a height of a space formed by the first surrounding groove and the second surrounding groove.

6. The substrate processing apparatus according to claim 1,
wherein the ring support surface includes:
a surrounding groove formed around the heat transfer gas supply hole;
a deep groove formed communicating with the surrounding groove and formed in a circumferential direction; and
a diffusion groove communicating with the surrounding groove and the deep groove and formed in a radial direction, and
wherein a depth of the deep groove is greater than a depth of the surrounding groove.

7. The substrate processing apparatus according to claim 1,
wherein the ring support surface includes:
a first diffusion groove formed in a radial direction; and
a first deep groove formed in a circumferential direction in a region other than the surrounding region around the heat transfer gas supply hole,
wherein the lower surface of the edge ring includes:
a second diffusion groove formed in the radial direction; and
a second deep groove formed in an annular shape, and
wherein a height of a space formed by the first deep groove and the second deep groove is greater than a height of a space formed by the first diffusion groove and the second diffusion groove.

8. The substrate processing apparatus according to claim 1,
wherein a first deep groove formed in a circumferential direction is formed in the ring support surface in a region other than the surrounding region around the heat transfer gas supply hole,
wherein the lower surface of the edge ring includes:
a second diffusion groove formed in a radial direction; and
a second deep groove formed in an annular shape, and
wherein a height of a space formed by the first deep groove and the second deep groove is greater than a height of a space formed by the second diffusion groove.

9. The substrate processing apparatus according to claim 1,
wherein the lower surface of the edge ring includes:
a surrounding groove formed around a position corresponding to the heat transfer gas supply hole;
a deep groove communicating with the surrounding groove and formed in a circumferential direction; and
a diffusion groove communicating with the surrounding groove and the deep groove and formed in a radial direction, and
wherein a depth of the deep groove is greater than a depth of the surrounding groove.

10. The substrate processing apparatus according to claim 1,
wherein the electrostatic chuck includes an electrostatic electrode situated in a ceramic member and configured to clamp the edge ring.

11. The substrate processing apparatus according to claim 10,
wherein the electrostatic chuck includes an inner seal band on an inner side of the groove in a radial direction and an outer seal band on an outer side of the groove in the radial direction,
wherein the electrostatic electrode includes a first electrostatic electrode and a second electrostatic electrode situated on an outer side of the first electrostatic electrode in the radial direction, and
wherein in the radial direction, the inner seal band and the first electrostatic electrode overlap at least partially, and the outer seal band and the second electrostatic electrode overlap at least partially.

12. The substrate processing apparatus according to claim 4,
wherein the height of the first space is in a range of 2 μm to 40 μm,
the height of the second space is in a range of 2 μm to 200 μm, and
the height of the third space is in a range of 1 μm to 25 μm.

13. The substrate processing apparatus according to claim 1,
wherein the surrounding region around the heat transfer gas supply hole is in a range of 1 mm to 10 mm from an outer periphery of the heat transfer gas supply hole in a circumferential direction.

14. An electrostatic chuck, comprising:
a substrate support surface configured to support a substrate; and
a ring support surface configured to support an edge ring,
wherein a groove in which a heat transfer gas is diffused is formed in the ring support surface,
wherein a heat transfer gas supply hole configured to supply the heat transfer gas into the groove is formed, and
wherein in an annular region including a position at which the heat transfer gas supply hole is formed, a depth of the groove in a surrounding region around the heat transfer gas supply hole is less than a depth of the groove in a region other than the surrounding region.

15. The electrostatic chuck according to claim 14,
wherein the groove includes a diffusion groove on an inner side of the annular region in a radial direction and on an outer side of the annular region in the radial direction.

16. The electrostatic chuck according to claim 14,
wherein the groove forms a space between the ring support surface and the lower surface of the edge ring, and
the space includes:
a first space communicating with the heat transfer gas supply hole;
a second space communicating with the first space and formed in a circumferential direction; and
a third space communicating with the first space and the second space and formed in a radial direction.

17. The electrostatic chuck according to claim 16,
wherein a height of the second space is greater than a height of the first space, and
wherein a height of the third space is less than the height of the first space.

18. The electrostatic chuck according to claim 14,
wherein the ring support surface includes:
a first surrounding groove formed around the heat transfer gas supply hole;
a first deep groove communicating with the first surrounding groove and formed in a circumferential direction; and
a first diffusion groove communicating with the first surrounding groove and the first deep groove and formed in a radial direction,
wherein the lower surface of the edge ring includes:
a second surrounding groove formed around a position corresponding to the heat transfer gas supply hole;
a second deep groove communicating with the second surrounding groove and formed in the circumferential direction; and
a second diffusion groove communicating with the second surrounding groove and the second deep groove and formed in the radial direction, and
wherein a height of a space formed by the first deep groove and the second deep groove is greater than a height of a space formed by the first surrounding groove and the second surrounding groove.

19. The electrostatic chuck according to claim 14,
wherein the ring support surface includes:
a surrounding groove formed around the heat transfer gas supply hole;
a deep groove formed communicating with the surrounding groove and formed in a circumferential direction; and
a diffusion groove communicating with the surrounding groove and the deep groove and formed in a radial direction, and
wherein a depth of the deep groove is greater than a depth of the surrounding groove.

20. The electrostatic chuck according to claim 14,
wherein the ring support surface includes:
a first diffusion groove formed in a radial direction; and
a first deep groove formed in a circumferential direction in a region other than the surrounding region around the heat transfer gas supply hole, and
wherein the lower surface of the edge ring includes:
a second diffusion groove formed in the radial direction; and
a second deep groove formed in an annular shape, and
wherein a height of a space formed by the first deep groove and the second deep groove is greater than a height of a space formed by the first diffusion groove and the second diffusion groove.
